(19) United States
(12) Patent Application Publication
(10) Pub. No.: US 2016/0163825 A1
(43) Pub. Date: Jun. 9, 2016

(54) MOSFET STRUCTURE AND METHOD OF MANUFACTURING SAME

(71) Applicant: INSTITUTE OF MICROELECTRONICS, CHINESE ACADEMY OF SCIENCES, Beijing (CN)

(72) Inventors: Haizhou Yin, Poughkeepsie, NY (US); Rui Li, Beijing (CN)

(21) Appl. No.: 14/905,151

(22) PCT Filed: Oct. 22, 2013
(86) PCT No.: PCT/CN2013/085650

§ 371 Date: Jan. 14, 2016

(30) Foreign Application Priority Data
Oct. 13, 2013 (CN) 201310476462.6

(51) Int. Cl. H01L 29/66; H01L 29/78; H01L 29/08; H01L 29/51; H01L 21/02

(52) U.S. Cl. CPC H01L 29/66545; H01L 29/513; H01L 29/6656; H01L 21/02164; H01L 29/0847; H01L 29/7833

(57) ABSTRACT

Provided are a MOSFET and a method for manufacturing the same. The method comprises: a. Providing a substrate (100), a dummy gate vacancy, a first spacer (150), source/drain extension regions (205), source/drain regions (200) and an interlayer dielectric layer (300); b. Depositing a silicon dioxide layer (160) in the dummy gate vacancy on the substrate; c. Depositing a gate dielectric layer (400) on the formed semiconductor structure; d. Forming a second spacer (450) in the dummy gate vacancy, wherein the second spacer (450) is adjacent to the gate dielectric layer (400) and is flushed with the interlayer dielectric layer (300); and e. Forming a gate stack (500) in the dummy gate vacancy . Negative effects caused by variation in thickness of the oxide layer under the gate can be eliminated, and device performance can be improved.

### TECHNICAL FIELD

The present disclosure relates to a Metal Oxide Semiconductor Field Effect Transistor (MOSFET) and a method for manufacturing the same. Specifically, the disclosure relates to a MOSFET which has an optimized gate structure and improved device performance, and a method for manufacturing the same.

### BACKGROUND

In MOSFET, the gate stack generally comprises a gate dielectric layer and a work function adjusting layer so as to optimize device performance. In addition, in order to improve interface performance between the gate dielectric layer and the channel material, a thin oxide layer is deposited on the channel before forming the gate dielectric layer so as to eliminate the interface state on a surface of the channel. In prior art, for a device having a silicon substrate, the silicon dioxide layer is generally formed by direct oxidation. Because the silicon dioxide is formed from the silicon in the substrate in thermal oxidation, the silicon under the spacer may not be oxidized due to block of the spacer at edges on both sides of the channel. Therefore, the silicon dioxide layer has a small thickness at edges on both sides of the channel than that on central portion of the channel. The closer to the spacer, the thinner the silicon dioxide layer is. Tht silicon dioxide layer has a slant (not planar) profile at edges on both sides of the channel. As a result, the gate dielectric layer and the work function adjusting layer deposited on the silicon dioxide layer subsequently may also have a slant profile, and a spike portion is formed at a portion close to the spacer. The distribution of the electric field may be influenced by the spike during operation of the device. The electric field lines are denser at the spike portion than at other positions, which may lead to negatived effects, such as Edge Crowding Effect of electric current.

Accordingly, the disclosure provides a MOSFET which has a optimized gate structure and improved device performance, and a method for manufacturing the same. Specifically, a second spacer is formed between the oxide layer on sidewalls of a first spacer on the channel and a gate dielectric layer. The second spacer has a thickness of about 3-7 nm, and covers the slant portion at edges of the silicon dioxide layer. Therefore, negative effects caused by variation of thickness of the oxide layer under the gate, and device performance can be optimized.

### SUMMARY OF INVENTION

The disclosure provides a MOSFET which has an optimized gate structure and improved device performance, and a method for manufacturing the same. Specifically, the disclosure provides a method for manufacturing a MOSFET comprising:

a. Providing a substrate, a dummy gate vacancy, a first spacer, source/drain extension regions, source/drain regions, and an interlayer dielectric layer;

b. Forming a silicon dioxide layer in the dummy gate vacancy on the substrate;

c. Depositing a gate dielectric layer on the formed semiconductor structure;

d. Forming a second spacer in the dummy gate vacancy, wherein the second spacer is adjacent to the gate dielectric layer, and is flushed with the interlayer dielectric layer;

e. Forming a gate stack in the dummy gate vacancy.

The boundary of the source/drain extension regions may extend to under the silicon dioxide layer, and the overlapping regions thereof may have a length equal to or larger than the total thickness of the second spacer and the gate dielectric layer .

The source/drain extension regions are formed by ion implantation towards a direction of the gate stack.

The second spacer has a thickness of about 3-7 nm.

Further, the present disclosure provides a semiconductor structure, comprising:

a substrate;

a silicon dioxide layer formed on the substrate;

a gate stack formed on the silicon dioxide layer;

a first spacer formed on the substrate on both sides of the gate stack;

source/drain regions formed on the substrate on both sides of the gate stack;

source/drain extension regions formed in the substrate on both sides of the gate stack; and

further comprising:

a gate dielectric layer formed between the gate stack and the silicon dioxide and on inner sidewalls of the first spacer; and

a second spacer formed between a portion of the gate dielectric layer adjacent to the first spacer and the gate stack 500, and located above the silicon dioxide layer.

The boundary of the source/drain extension regions may extend to under the silicon dioxide layer, and the overlapping regions thereof may have a length equal to or larger than the total thickness of the second spacer and the gate dielectric layer.

The second spacer has a thickness of about 3-7 nm.

In the present disclosure, a MOSFET having an optimized gate structure and improved device performance and a method for manufacturing the same are provided. Specifically, a second spacer is formed between the oxide layer on sidewalls of a first spacer on the channel and a gate dielectric layer. The second spacer has a thickness of about 3-7 nm, and covers the slant portion at edges of the silicon dioxide layer. Therefore, negative effects caused by variation of thickness of the oxide layer under the gate, and device performance can be optimized.

### DESCRIPTION OF DRAWINGS

FIG. 1 to FIG. 7 illustrate cross-section diagrams of the semiconductor structure in various stages of a method according to an embodiment of the present disclosure.

### DETAILED DESCRIPTION

In the following, in order to make objectives, technical solutions and advantages of the present disclosure more clearer, embodiments of the present disclosure will be described in detail in connection with the attached drawings.

Hereinafter, embodiments of the present disclosure are described. Examples of the embodiments are shown in the attached drawings. The same or similar reference numbers denote the same or similar elements or elements having the same or similar function throughout the drawings. Embodiments described with reference to the drawings are illustrative only, and are intended to interpret the invention rather than limiting the invention.

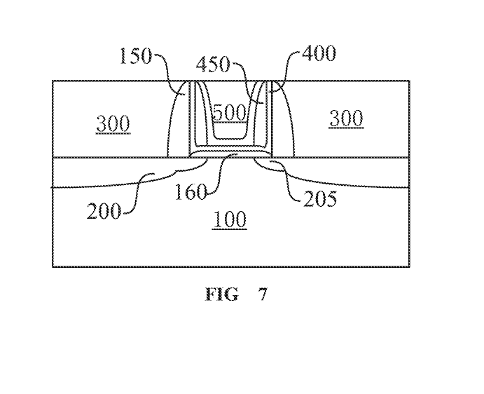

As shown in FIG. 7, the present disclosure provides a semiconductor structure, comprising:

a substrate 100;

a silicon dioxide layer 160 formed on the substrate 100;

a gate stack 500 formed on the silicon dioxide layer 160;

a first spacer 150 formed on the substrate 100 on both sides of the gate stack 500;

source/drain regions 200 formed on the substrate 100 on both sides of the gate stack 500;

source/drain extension regions 205 formed on the substrate 100 on both sides of the gate stack 500;

further comprising:

a gate dielectric layer 400 formed between the gate stack 500 and the silicon dioxide 160 and on inner sidewalls of the first spacer 150;

a second spacer 450 formed between a portion of the gate dielectric layer 400 adjacent to the first spacer 150 and the gate stack 500, and located above the silicon dioxide layer 160.

The gate stack comprises a work function adjusting layer and a metal gate layer. The metal gate layer may be a metal gate, or a composite gate of metal/polysilicon with silicide formed on the polysilicon. The gate dielectric layer may be preferably silicon oxynitride, silicon oxide or high-k materials. The gate dielctric layer may have a Equivalent Oxide Thickness (EOT) of about 0.5-5 nm.

The semiconductor channel is located on a surface of the substrate 100, may be preferably made of single crystalline silicon, and may have a thickness of about 2-20 nm. The channel may be lightly doped or undoped. In a case where the channel is doped, the channel may have a doping type opposite to that of the source/drain regions.

The source/drain regions are located in the substrate 100 on both sides of the gate stack. The source/drain regions are symmetric and have a doping type opposite to that of the substrate.

The boundary of the source/drain extension regions 205 may extend to under the silicon dioxide layer 160, and the overlapping regions thereof may have a length equal to or larger than the total thickness of the second spacer 450 and the gate dielectric layer 400.

In formation of the silicon dioxide layer 160, there may exist a slant region between adjacent regions of the silicon dioxide layer 160 and the first spacer 150. If the gate is directly formed on the silicon dioxide layer, various negative effects (such as Edge Crowding Effect of electric current) caused by thickness variation of the silicon dioxide layer 160 under the gate and the too thin thickness of the silicon dioxide layer near the boundary may introduce defects into the gate dielectric layer due to hot carriers punching through the silicon dioxide layer 160.

In the present disclosure, the second spacer having a thickness of about 3-7 nm may be formed above the boundary between the silicon dioxide layer 160 and the first spacer 150 to cover the slant region at edges of the silicon dioxide layer. Negative effects caused by the variation of the thickness of the silicon dioxide layer under the gate can be eliminated, and device performance can be improved.

In the following, the manufacturing method is described in connection with the attached drawings. It shoud be noted that the drawings in embodiments of the present disclosure are illustrative only, and are not drawn to scale.

Firstly, a substrate is provided, and a dummy gate 101is formed on the substrate. The dummy gate may be a single-layer structure, or may be a multi-layer structure. The dummy gate 101 may be made of polymer materials, amorphous silicon, polysilicon or TiN, and may have a thickness of about 10-200 nm. In the present embodiment, the dummy gate may comprise polysilicon and silicon dioxide. Specifically, polysilicon may be filled into the gate vacancy by Chemical Vapor Deposition (CVD). Then, a silicon dioxide layer is formed on the polysilicon layer by, for example, epitaxially growing, oxidation or CVD, etc. Next, photolighgraphy and etching in conventional CMOS processes are performed to the deposited dummy gate so as to form gate electrode patterns. Then the exposed gate dielectric layer is etched off with the gate electrode patterns as a mask. It should be noted that if not stated otherwise, the deposition of various dielctric materials in the present embodiment may be formed by the method for forming the gate dielectric layer described above, and may be omitted here.

Next, the substrate 100 on both sides of the dummy gate may be lightly doped to form source/drain extension regions 205. Halo implantation may also be performed to form halo implantation regions. The dopants for the source/drain extension regions 205 may be the same as that of the device, and the dopants for halo implantation may be opposite to that of the device. Specifically, the source/drain regions 205 may be formed by tilt ion implantation so that the boundary of the source/drain extension regions 205 extends to under the dummy gate vacancy.

Next, a first spacer 150 is formed on sidewalls of the gate stack to isolate the gate electrode. Specifically, a sacrificial spacer dielectric layer of silicon nitride with a thickness of about 40-80 nm may be deposited by LPCVD. The first spacer 150 may also be formed of silicon oxide, silicon oxynitride, silicon carbide or combinations thereof, and/or other appropriate materials. The first spacer 150 may have a multi-layer structure. The first spacer 150 may be formed by processes such as deposition and etching, and may have a thickness of about 10-100 nm, for example, 30 nm, 50 nm or 80 nm.

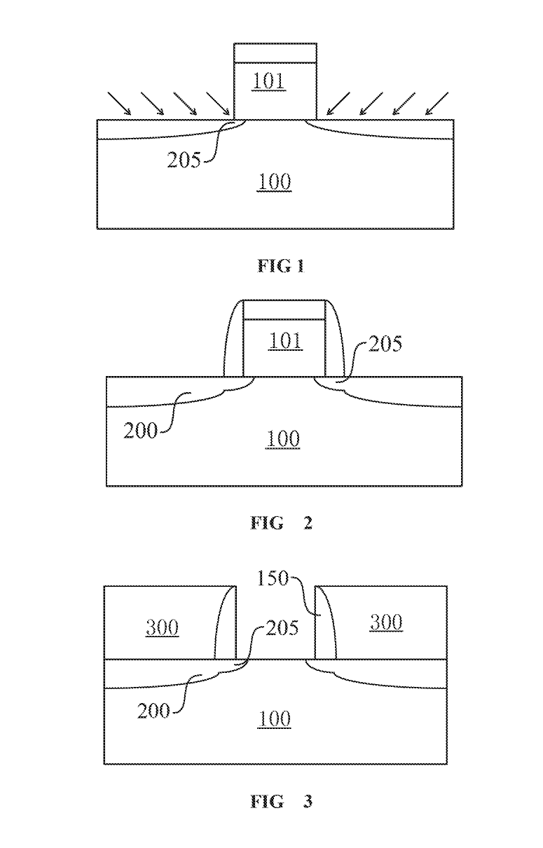

Next, a dielectric layer of silicon dioxide with a thickness of about 10-35 nm may be deposited on the semiconductor structure to form an interlayer dielectric layer 300. Then, ion implantation may be performed to the source/drain regions with the dielectric layer as a buffer layer. For p-type crystal, the dopants may be B, BF₂, In, or Ga. For n-type crystal, the dopants may be P, As, or Sb. The doping concentration may be 5e10¹⁹cm⁻³-1e10²⁰ cm⁻³. The semiconductor structure after doping is shown in FIG. 2.

Next, the dummy gate is removed to form a dummy gate vacancy, as shown in FIG. 3. The dummy gate may be removed by wet etching and/or dry etching. In one embodiment, plasma etching is performed.

Next, a silicon dioxide layer 160 is formed on a surface of the channel in the dummy gate vacancy, as shown in FIG. 4. Specifically, the silicon dioxide layer 160 is formed by dry oxidation. Because in the oxidation, the silicon in the silicon dioxide layer comes from the substrate, the silicon dioxide layer has a thickness at edges of the channel much thinner than that in the middle portion of the channel. Because theere exists much less silicon at portions close to the spacer, the formed silicon dioxide layer becomes much thinner. Therefore, the silicon dioxide layer has a slant profile at positions close to the spacer, as shown in FIG. 4.

If the gate is directly formed on the silicon dioxide layer, various negative effects (such as Edge Crowding Effect of electric current) caused by thickness variation of the silicon dioxide layer 160 under the gate and the too thin thickness of the silicon dioxide layer near the boundary may introduce defects into the gate dielectric layer due to hot carriers punching through the silicon dioxide layer 160.

In the present disclosure, the second spacer may be formed above the boundary between the silicon dioxide layer 160 and the first spacer 150 to cover the slant region at edges of the silicon dioxide layer. Negative effects caused by the variation of the thickness of the silicon dioxide layer under the gate can be eliminated, and device performance can be improved.

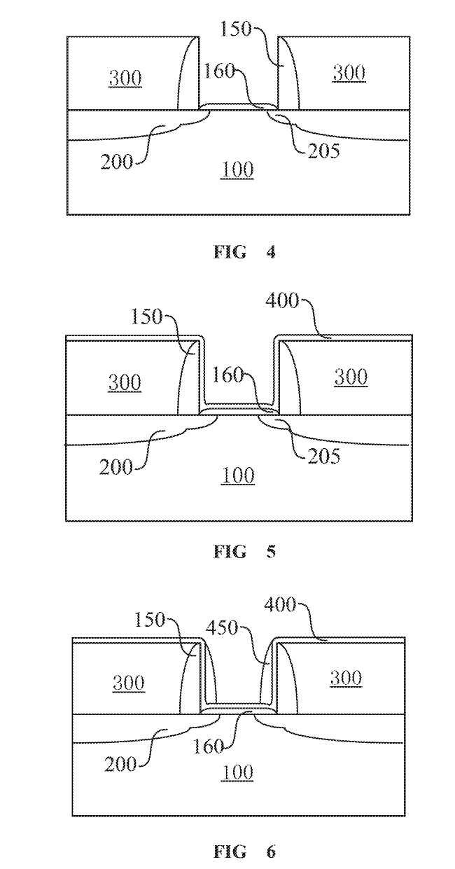

Next, a gate dielectric layer 400 is deposited on the silicon dioxide layer 160, as shown in FIG. 5. Specifically, the gate dielectric layer may be a thermal oxidation layer, such as silicon oxide, silicon oxynitride, or may be high-k dielectric materials, such as HfAlON, HfSiAlON, HfTaAlON, HfTiAlON, HfON, HfSiON, HfTaON, HfTiON, Al₂O₃, La₂O₃, ZrO₂, LaAlO or combinations therof. The gate dielectric layer may have a thickness of about 1-10 nm, for example, 3 nm, 5 nm, or 8 nm, and the EOT thereof is 0.5-5 nm. The gate dielectric layer may be formed by thermal oxidation, CVD or Atomic Layer Deposition (ALD). The gate dielectric layer 400 may have the same profile as that of the silicon dioxide layer 160, i.e., may have a slant profile at a position close to the first spacer 150 above the channel.

Next, as shown in FIG. 6, a second spacer 450 is formed on vertical sidewalls of the gate dielectric layer. Specifically, a sacrificial spacer dielectric layer of silicon nitride with a thickness of about 40-80 nm may be deposited by LPCVD. Then, the second spacer 450 of silicon nitride with a thickness of about 35-75 nm is formed on vertical sidewalls of the gate dielectric layer by a etching back process. The second spacer 450 may also be formed of silicon oxide, silicon oxynitride, silicon carbide or combinations thereof, and/or other materials as appropriate. The second spacer having a thickness of about 3-7 nm may be formed to cover the slant region at edges of the silicon dioxide layer. Negative effects caused by the variation of the thickness of the silicon dioxide layer under the gate can be eliminated, and device performance can be improved.

The boundary of the source/drain extension regions 205 may extend to under the silicon dioxide layer 160, and the overlapping regions thereof may have a length equal to or larger than the total thickness of the second spacer 450 and the gate dielectric layer 400. When an inversion channel is formed from the substrate under the gate stack, the source/drain extension regions 205 may be connected by the inversion channel, and the device may operate normally.

Next, the gate stack 500 may be formed in the gate vacancy. The gate stack comprises a work function adjusting layer and a metal gate layer. The metal gate layer may be a metal gate, or a composite gate of metal/polysilicon with silicide formed on the polysilicon. As shown in FIG. 7, preferably, the work function layer may be deposited on the gate dielectric layer. Then a metal gate layer may be formed on the work function adjusting layer. The work function adjusting layer may be formed of TiN, TaN, etc., and may have a thickness of about 3-15 nm. The metal gate layer may be a single-layer or multi-layer structure. The metal gate layer may be formed of TaN, TaC, TiN, TaAlN, TiAlN, Mol1N, TaTbN, TaErN, TaYbN, TaSiN, HfSiN, MoSiN, RuTaₓ, NiTaₓ, or combinations thereof. The metal gate layer may have a thickness of about 10-40 nm, for example, 20 nm or 30 nm.

Although the exemplary embodiments and their advantages have been described in detail, it should be understood that various alternations, substitutions and modifications may be made to the embodiments without departing from the spirit of the present invention and the scope as defined by the appended claims. For other examples, it may be easily recognized by a person of ordinary skill in the art that the order of processing steps may be changed without departing from the scope of the present invention.

In the present disclosure, a MOSFET having an optimized gate structure and improved device performance and a method for manufacturing the same are provided. Specifically, a second spacer is formed between the oxide layer on sidewalls of a first spacer on the channel and a gate dielectric layer. The second spacer has a thickness of about 3-7 nm, and covers the slant portion at edges of the silicon dioxide layer. Therefore, negative effects caused by variation of thickness of the oxide layer under the gate, and device performance can be optimized.

In addition, the scope to which the present invention is applied is not limited to the process, mechanism, manufacture, material composition, means, methods and steps described in the specific embodiments in the specification According to the disclosure of the present invention, a person of ordinary skill in the art would readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

1. A method for manufacturing a MOSFET, comprising:
a. Providing a substrate (100), a dummy gate vacancy, a first spacer (150), source/drain extension regions (205), source/drain regions (200), and an interlayer dielectric layer (300);
b. Forming a silicon dioxide layer (160) in the dummy gate vacancy on the substrate;
c. Depositing a gate dielectric layer (400) on the formed semiconductor structure;
d. Forming a second spacer (450) in the dummy gate vacancy, wherein the second spacer (450) is adjacent to the gate dielectric layer (400), and is flushed with the interlayer dielectric layer (300);
e. Forming a gate stack (500) in the dummy gate vacancy.

2. The method of claim 1, wherein boundary of the source/drain extension regions (205) extends to under the silicon dioxide layer (160), and overlapping regions thereof have a length equal to or larger than total thickness of the second spacer (450) and the gate dielectric layer (400).

3. The method of claim 1, wherein the source/drain extension regions (205) are formed by ion implantation towards a direction of the gate stack.

4. The method of claim 1, wherein the second spacer (450) has a thickness of about 3-7 nm.

5. A semiconductor structure, comprising:
a substrate (100);
a silicon dioxide layer (160) formed on the substrate (100);
a gate stack (500) formed on the silicon dioxide layer (160);
a first spacer (150) formed on the substrate (100) on both sides of the gate stack (500);
source/drain regions (200) formed on the substrate (100) on both sides of the gate stack (500);
source/drain extension regions (205) formed on the substrate (100) on both sides of the gate stack (500); and
further comprising:
a gate dielectric layer (400) formed between the gate stack (500) and the silicon dioxide (160) and on inner sidewalls of the first spacer (150); and
a second spacer (450) formed between a portion of the gate dielectric layer (400) adjacent to the first spacer (150) and the gate stack (500), and located above the silicon dioxide layer (160).

6. The semiconductor structure of claim 5, wherein boundary of the source/drain extension regions (205) extends to under the silicon dioxide layer (160), and overlapping regions thereof have a length equal to or larger than total thickness of the second spacer (450) and the gate dielectric layer (400).

7. The semiconductor structure of claim 5, wherein the second spacer (450) has a thickness of about 3-7 nm.
